(19) United States
(12) Patent Application Publication
(10) Pub. No.: US 2014/0160678 A1
(43) Pub. Date: Jun. 12, 2014

(54) FAN DRIVING SYSTEM AND ELECTRONIC DEVICE USING SAME

(71) Applicants: Hon Hai Precision Industry Co., Ltd., New Taipei (TW); Hong Fu Jin Precision Industry (WuHan) Co., Ltd., Wuhan (CN)

(72) Inventor: CHUN-SHENG CHEN, New Taipei (TW)

(73) Assignees: HON HAI PRECISION INDUSTRY CO., LTD., New Taipei (TW); HONG FU JIN PRECISION INDUSTRY (WUHAN) CO., LTD., Wuhan (CN)

(21) Appl. No.: 14/101,369

(22) Filed: Dec. 10, 2013

(30) Foreign Application Priority Data
Dec. 11, 2012 (CN) 2012105303478

(51) Int. Cl. H05K 7/20

(52) U.S. Cl. CPC H05K 7/20209; H05K 7/20172
USPC 361/695; 415/118

(57) ABSTRACT

A fan driving system includes a fan connector, a fan mounted onto the fan connector, and a main circuit board. The main circuit board includes a detection module and an alarm circuit, the detection module is electrically connected between the fan connector and the alarm circuit. The detection module is configured to detect an electrical connectivity between the fan and the fan connector, and enabling the alarm circuit to set an alarm when detecting the electrical connectivity between the fan and fan connector is poor.

### CROSS-REFERENCE TO RELATED APPLICATIONS

This application claims all benefits accruing under 35 U.S.C. §119 from China Patent Application No. 201210530347.8, filed on Dec. 11, 2012 in the China Intellectual Property Office, the content of which is hereby incorporated by reference.

### BACKGROUND

1. Technical Field

The present disclosure relates to a fan driving system and an electronic device using the fan driving system.

2. Description of Related Art

Fans are widely used in electronic devices to dissipate heat from integrated circuit (IC) circuits, such as a central processing unit (CPU), in the electronic devices. Typically, a fan is mounted onto and electrically connected to a fan connector of a control circuit board, and electrically connected to a fan driver on the circuit board. In operation, the fan driver outputs driving signals to the fan via the fan connector, and the driving signals drive the fan to run and cool a circuit. However, after long-term use, the fan may not be firmly mounted onto the fan connector, and this may cause the fan to be poorly connected to the fan connector. In this circumstance, the driving signals cannot be transmitted to the fan, and the fan cannot be driven to function. As such, the heat cannot be dissipated from the circuit and a lifetime of the circuit may be reduced.

What is needed is to provide a means that can overcome the above-described limitations.

### BRIEF DESCRIPTION OF THE DRAWINGS

The components in the drawings are not necessarily drawn to scale, the emphasis instead being placed upon clearly illustrating the principles of at least one embodiment. In the drawings, like reference numerals designate corresponding parts throughout the various views.

FIG. 1 is a schematic block diagram of fan driving system according to an embodiment of the present disclosure.

FIG. 2 is schematic block diagram of an electronic device using the fan driving system of FIG. 1.

### DETAILED DESCRIPTION

Reference will now be made to the drawings to describe various embodiments in detail.

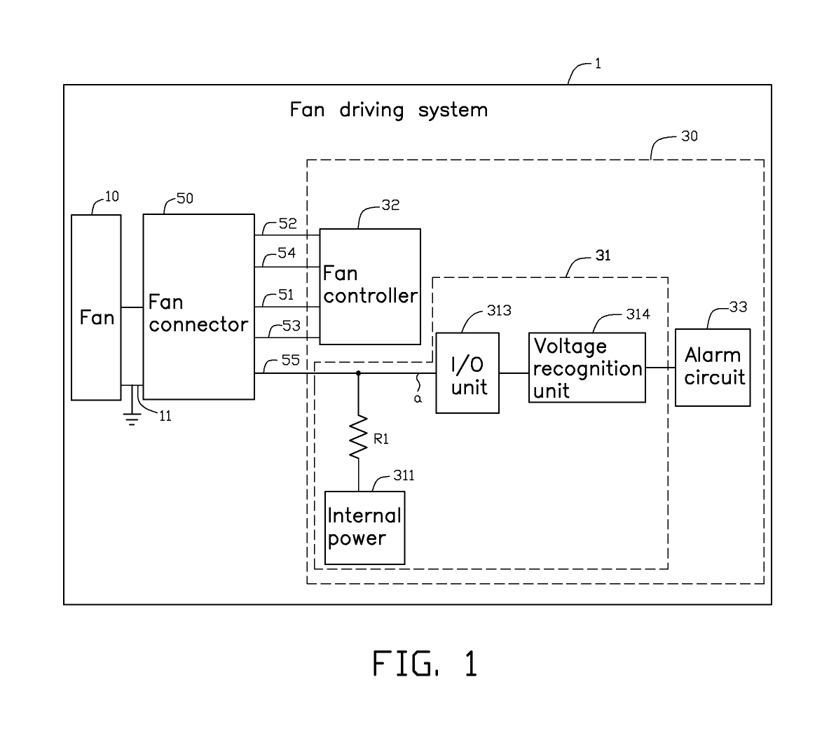

A fan driving system according to an embodiment of the present disclosure is illustrated in FIG. 1, the fan driving system 1 may be used in an electronic device such as a computer. The fan driving system 1 includes a fan 10, a fan connector 50, and a main circuit board 30. The fan 10 is mounted onto and electrically connected to the fan connector 50, and the fan connector 50 provides electrical connection between the fan 10 and the main circuit board 30.

The main circuit board 30 may be a motherboard in the computer, and includes a detection module 31, a fan controller 32, and an alarm circuit 33. The detection module 31 and the fan controller 32 are both electrically connected to the fan connector 50, and the alarm circuit 33 is electrically connected to the detection module 31.

The fan controller 32 is configured to provide driving signals to the fan 10 via the fan connector 50 and thereby driving the fan 10 to run and dissipate heat from circuits inside the electronic device, such as a CPU circuit. In particular, the fan connector 50 includes a ground terminal 51, a power terminal 52, a feedback terminal 53 and a control terminal 54, all of which are electrically connected to the fan controller 32.

The power terminal 52 may receive a power voltage from the fan controller 32 or an external power supply, and the control terminal 54 receives a control signal from the fan controller 32. The fan connector 50 forwards the power signal and the control signal to the fan 10, and the fan 10 is driven in accordance with the control signal. During operation, the fan 10 may output a feedback signal indicating a current rotation rate of a fan blade thereof to the fan controller 32 via the feedback terminal 53, and the fan controller 32 may further adjust rotation rate of the fan blade using the control signal.

The detection module 31 is electrically connected between the fan connector 50 and the alarm circuit 33. The detection module 31 may detect an electrical connectivity between the fan 10 and the fan connector 50, and when poor connection between the fan 10 and the fan connector 50 is detected, the detection module 31 may enable the alarm circuit 33 to alarm. The poor connection may be defined as the electrical connectivity between the fan 10 and fan connector 50 is poor, for example, the fan 10 is disconnected with the fan connector 50.

To cooperate the connectivity detection of the detection module 31, the fan 10 may include a detecting pin 11 and the fan connector 50 may further include a detecting terminal 55. When the fan 10 is mounted onto the fan connector 50, the detecting pin 11 of the fan 10 is plugged into a predetermined slot in the fan connector 50 and contacts the detecting terminal 55. Moreover, the detecting pin 11 of the fan 10 may be provided with a first voltage; for example, in one embodiment, the detecting pin 11 may be grounded so that the detecting pin 11 is provided with a ground voltage of 0V (volt); in another embodiment, the detecting pin 11 may alternatively be electrically coupled to an extra power unit to receive a positive or negative voltage so that the first voltage is the positive or negative voltage; in yet another embodiment, the detecting pin 11 may alternatively be electrically coupled to the power terminal 52 of the fan connector 50 so that the first voltage is the power voltage.

The detection module 31 includes an internal power 311, an input/output (I/O) unit 313 and a voltage recognition unit 314. The internal power 311 is electrically connected to the detecting terminal 55 of the fan connector 50 via a resistor 312, and is configured to provide a second voltage which is substantially different from the first voltage. The I/O unit 313 may be an I/O circuit of the motherboard, and includes a general purpose input output (GPIO) port (labeled “a”) which is also electrically connected to the detecting terminal 55 of the fan connector 50. The voltage recognition unit 314 may be a basic input output system (BIOS) circuit of the motherboard, is electrically connected between the I/O unit 313 and the alarm circuit 33.

For example, when the fan 10 is well connected with the fan connector 50, the detecting pin 11 of the fan 10 contacts the detecting terminal 55 of the fan connector 50 and thus the detecting terminal 55 is pulled down to the first voltage such as the ground voltage of 0V. The first voltage is input to the I/O unit 313 via the GPIO port, and then be output to the voltage recognition unit 314 by the I/O unit 313. The voltage recognition unit 314 recognizes the received voltage is the first voltage and then determines that the electrical connectivity is fine.

When the fan 10 is poor connected with the fan connector 50, the detecting terminal 55 of the connector 50 is pulled up to a second voltage by the internal power 311, which is different from the first voltage. The second voltage is input to the I/O unit 313 via the GPIO port, and then be output to the voltage recognition unit 314 by the I/O unit 313. The voltage recognition unit 314 recognizes the received voltage is the second voltage and then determines that the electrical connectivity between the fan 10 and the fan connector 50 is bad. Accordingly, the voltage recognition unit 314 may further provides an enablement signal to the alarm circuit 33.

The alarm circuit 33 may set an alarm to notify the user of the poor connection between the fan 10 and the fan connecter 50 according to the enablement signal output by the voltage recognition unit 314. For example, the alarm circuit 33 may be an alarm lamp which is turned on when receiving the enablement signal, or a speaker which plays an alarm audio when receiving the enablement signal, or a vibrator which is vibrated when receiving the enablement signal, or a make a buzzing sound when receiving the enablement signal.

In the above-described fan driving system 1, the detection module 31 is capable of detecting the connectivity between the fan 10 and the fan connector 50, and the alarm circuit 33 set an alarm when the fan 10 is poor connected to the fan connector 50, therefore, the user can be aware of the connection status of the fan 10, and make necessary maintenance to ensure the fan 10 to keep on working. As such, the heat of the circuit can be dissipated by the fan 10.

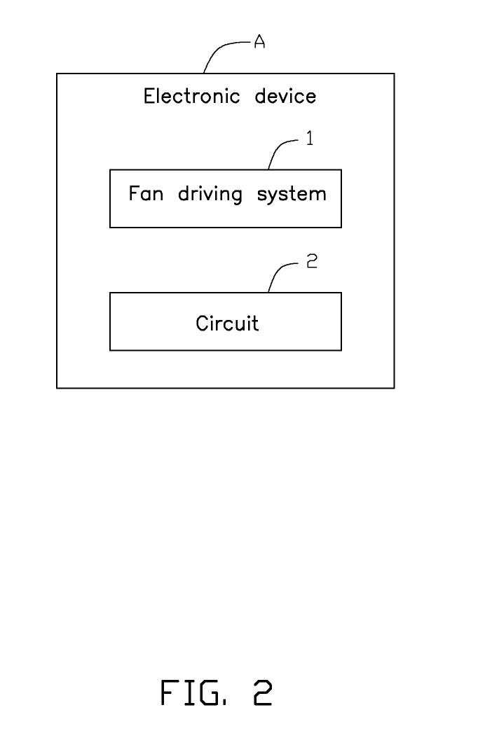

FIG. 2 is schematic block diagram of an electronic device using the fan driving system of FIG. 1. The electronic device A includes a fan driving system 1 as illustrated in FIG. 1 and a circuit 2. The fan driving system 1 is disposed adjacent to the circuit 2, and the fan driving system 1 includes a fan for dissipating heat from the circuit 2.

It is to be understood that even though numerous characteristics and advantages of the present embodiments have been set forth in the foregoing description, together with details of the structures and functions of the embodiments, the disclosure is illustrative only; and that changes may be made in detail, especially in matters of shape, size, and arrangement of parts, within the principles of the embodiments, to the full extent indicated by the broad general meaning of the terms in which the appended claims are expressed.

What is claimed is:

1. A fan driving system, comprising:
a fan connector;
a fan mounted onto the fan connector; and
a main circuit board comprising a detection module and an alarm circuit, the detection module being electrically connected between the fan connector and the alarm circuit;
wherein the detection module is configured to detect an electrical connectivity between the fan and the fan connector, and enabling the alarm circuit to alarm when the electrical connectivity between the fan and fan connector is poor.

2. The fan driving system of claim 1, wherein the fan comprises a detecting pin, and the fan controller comprises a detecting terminal, the detecting pin of the fan is plugged into a predetermined slot in the fan connector and contacts the detecting terminal when fan is mounted onto the fan connector.

3. The fan driving system of claim 2, wherein the detecting pin is provided with a first voltage.

4. The fan driving system of claim 3, wherein the detection module comprises an internal power electrically connected to the detecting terminal of the fan connector via a resistor, the internal power is configured to provide a second voltage substantially different from the first voltage.

5. The fan driving system of claim 3, wherein the detection module further comprises an input/output (I/O) unit and a voltage recognition unit, the I/O unit is electrically connected to the detecting terminal of the fan connector, and the voltage recognition unit is electrically connected between the I/O unit and the alarm circuit.

6. The fan driving system of claim 5, wherein the I/O unit is configured to output a current voltage of the detecting terminal to the voltage recognition unit, and the voltage recognition unit is configured to provide an enablement signal to the alarm circuit when recognizing the current voltage of the detecting terminal is the second voltage.

7. The fan driving system of claim 2, wherein the detecting pin of the fan is grounded and the first voltage is the ground voltage.

8. The fan driving system of claim 2, wherein the main circuit board further comprises a fan controller, the fan connector further comprises a power terminal electrically connected to the fan controller, the power terminal is configured to receive a power voltage.

9. The fan driving system of claim 8, wherein the detecting pin of the fan is electrically connected to the power terminal of the fan connector, and the first voltage is the power voltage.

10. The fan driving system of claim 2, wherein the detecting pin is electrically connected to an extra power unit to receive a positive or negative voltage, and the first voltage is the positive or negative voltage.

11. An electronic device, comprising:
a circuit; and
a fan driving system disposed adjacent to the circuit, the fan driving system comprising:
a fan connector;
a fan mounted onto the fan connector and configured for dissipating heat from the circuit; and
a main circuit board comprising a detection module and an alarm circuit, the detection module being electrically connected between the fan connector and the alarm circuit;
wherein the detection module is configured to detect an electrical connectivity between the fan and the fan connector, and enabling the alarm circuit to alarm when detecting the electrical connectivity between the fan and fan connector is poor.

12. The electronic device of claim 11, wherein the fan comprises a detecting pin, and the fan controller comprises a detecting terminal, the detecting pin of the fan is plugged into a predetermined slot in the fan connector and contacts the detecting terminal when fan is mounted onto the fan connector.

13. The electronic device of claim 12, wherein the detecting pin is provided with a first voltage.

14. The electronic device of claim 13, wherein the detection module comprises an internal power electrically connected to the detecting terminal of the fan connector via a resistor, the internal power is configured to provide a second voltage substantially different from the first voltage.

15. The electronic device of claim 13, wherein the detection module further comprises an input/output (I/O) unit and a voltage recognition unit, the I/O unit is electrically connected to the detecting terminal of the fan connector, and the voltage recognition unit is electrically connected between the I/O unit and the alarm circuit.

16. The electronic device of claim 15, wherein the I/O unit is configured to output a current voltage of the detecting terminal to the voltage recognition unit, and the voltage recognition unit is configured to provide an enablement signal to the alarm circuit when recognizing the current voltage of the detecting terminal is the second voltage.

17. The electronic device of claim 12, wherein the detecting pin of the fan is grounded and the first voltage is the ground voltage.

18. The electronic device of claim 12, wherein the main circuit board further comprises a fan controller, the fan connector further comprises a power terminal electrically connected to the fan controller, the power terminal is configured to receive a power voltage.

19. The electronic device of claim 18, wherein the detecting pin of the fan is electrically connected to the power terminal of the fan connector, and the first voltage is the power voltage.

20. The electronic device of claim 12, wherein the detecting pin is electrically connected to an extra power unit to receive a positive or negative voltage, and the first voltage is the positive or negative voltage.
